(19) United States
(12) Patent Application Publication
(10) Pub. No.: US 2015/0204938 A1
(43) Pub. Date: Jul. 23, 2015

(54) CLOCK CONTROLLER AND SEMICONDUCTOR DEVICE INCLUDING THE SAME

(71) Applicant: SK hynix Inc., Gyeonggi-do (KR)

(72) Inventor: Dong-Uk LEE, Gyeonggi-do (KR)

(21) Appl. No.: 14/305,963

(22) Filed: Jun. 16, 2014

(30) Foreign Application Priority Data
Jan. 20, 2014 (KR) 10-2014-0006719

(51) Int. Cl. G01R 31/26; H03K 5/1534; H03K 5/06

(52) U.S. Cl. CPC G01R 31/2601; H03K 5/065; H03K 5/1534; H03K 2005/00293

(57) ABSTRACT

A dock controller may include a dock period detector suitable for delaying a first dock signal through a plurality of unit delay circuits, and outputting a detection signal by detecting a period of the first dock signal as the number of unit delay circuits used for unit delay of the first clock signal among the unit delay circuits; and a clock generator suitable for generating a delay clock signal delayed by a half period of the first dock signal in response to the detection signal outputted from the clock period detector, and generating a second clock signal having a period corresponding to edges of the first clock signal and the delay clock signal.

### CROSS-REFERENCE TO RELATED APPLICATIONS

The present application claims priority of Korean Patent Application No. 10-2014-0006719, filed on Jan. 20, 2014, which is incorporated herein by reference in its entirety.

### BACKGROUND

1. Field

Exemplary embodiments of the present invention relate to a semiconductor design technology, and more particularly, to a test device including a clock controller and a semiconductor device including the same.

2. Description of the Related Art

As the operating speed of semiconductor devices increases, the operating speed of testers for testing semiconductor devices may not keep up with the operating speeds of the semiconductor devices.

For example, although the semiconductor device operates at a frequency of up to 400 MHz, the tester may not generate a signal frequency which exceeds 200 MHz. In this case, when the tester tests the semiconductor device at a frequency of 200 MHz, it may take a long time to perform the test. Furthermore, the tester cannot conduct a proper test for high speed semiconductor devices.

### SUMMARY

Various embodiments of the present invention are directed to a semiconductor device capable of performing a high-frequency operation through clock doubling during a test operation.

In an embodiment, a clock controller may include a clock period detector suitable for delaying a first clock signal through a plurality of unit delay circuits, and outputting a detection signal by detecting a period of the first clock signal as the number of unit delay circuits used for unit delay of the first clock signal among the unit delay circuits; and a clock generator suitable for generating a delay clock signal delayed by a half period of the first clock signal in response to the detection signal outputted from the clock period detector, and generating a second clock signal having a period corresponding to edges of the first clock signal and the delay clock signal.

In an embodiment, a test device may include a buffering unit suitable for receiving a command and a first clock signal from an external source, buffering the command and the first clock signal, and outputting an internal command and an internal clock signal; a command synchronization unit suitable for synchronizing the internal command with the internal clock signal to output a synchronized command; a clock doubling unit suitable for detecting a unit delay time of the internal dock signal in response to the internal dock signal, and generating a second clock signal having a period corresponding to a half period of the unit delay time; a high-speed command synchronization unit suitable for synchronizing the synchronized command outputted from the command synchronization unit with the second clock signal to output a high-speed command; and a plurality of selection units suitable for selectively outputting the internal dock signal and the synchronized command outputted from the command synchronization unit or the second clock signal and the high-speed command synchronized with the second-frequency clock signal, in response to a test signal.

In an embodiment, a semiconductor device may include a test circuit suitable for receiving a first clock signal and a first command from an external source, generating a second clock signal having a period corresponding to a half period of the first clock signal, and outputting the second clock signal and a second command synchronized with the second clock signal during a test operation; and a memory driver suitable for operating in response to the second clock signal and the second command synchronized with the second clock signal from the test circuit during the test operation.

In an embodiment, a test method may include converting a first-frequency clock signal inputted from an external source into a second-frequency clock signal during a test operation; serially sorting command signals, which are sequentially inputted in parallel through first and second command pads, in response to the second-frequency dock signal; and performing an internal test operation in response to command signals which are sorted through the serially sorting.

In an embodiment, a semiconductor device may include a dock doubling unit suitable for detecting a unit delay time of a first dock signal, and generating a second clock signal having a period corresponding to a half period of the first clock signal based on the unit delay time; a command synchronization unit suitable for synchronizing a command with the first clock signal to output a first command; a high-speed command synchronization unit suitable for synchronizing the first command with the second clock signal to output a second command; a plurality of selection units suitable for selectively outputting the first command and the first clock signal or the second command and the second clock signal in response to a test signal; and a memory driver suitable for operating in response to the first command and the first clock signal while performing a test operation in response to the second command and the second clock signal.

### BRIEF DESCRIPTION OF THE DRAWINGS

FIG. 1 is a block diagram illustrating a semiconductor device in accordance with an embodiment of the present invention.

FIG. 2 is a detailed block diagram of a command synchronization unit which is a component of a test circuit of FIG. 1 in accordance with the embodiment of the present invention.

FIG. 3 is a detailed block diagram of a clock doubling unit which is a component of the test circuit of FIG. 1 in accordance with the embodiment of the present invention.

FIG. 4 is a detailed block diagram of a clock period detector which is a component of the clock doubling unit of FIG. 3 in accordance with the embodiment of the present invention.

FIG. 5 is a detailed block diagram of a clock generator which is a component of the clock doubling unit of FIG. 3 in accordance with the embodiment of the present invention.

FIG. 6 is a detailed block diagram of a delay chain which is a component of the clock generator of FIG. 5 in accordance with the embodiment of the present invention.

FIG. 7 is a timing diagram illustrating the operation of the clock doubling unit of FIG. 3 in accordance with the embodiment of the present invention.

FIG. 8 is a detailed block diagram of a high-speed command synchronization unit which is a component of the test circuit of FIG. 1 in accordance with the embodiment of the present invention.

FIG. 9 is a timing diagram of the operation of the semiconductor device illustrated in FIGS. 1 to 8.

FIG. 10 is a circuit diagram of a write circuit for writing data using a high-speed clock signal generated by the clock doubling unit of FIG. 1.

FIG. 11 is a timing diagram illustrating the operation of the write circuit of FIG. 10.

FIG. 12 is a circuit diagram of a circuit in which the number of command pads is doubled in accordance with another embodiment of the present invention.

FIG. 13 is a timing diagram illustrating the operation of the circuit of FIG. 12.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts in the various figures and embodiments of the present invention.

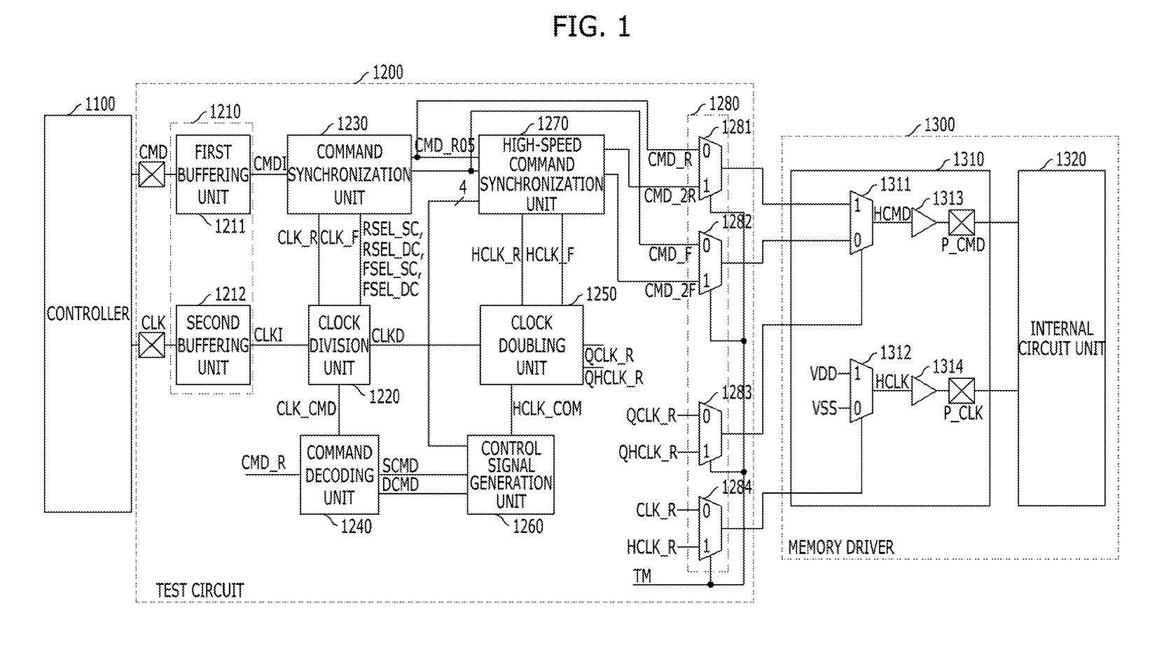

FIG. 1 is a block diagram illustrating a semiconductor device in accordance with an embodiment of the present invention.

Referring to FIG. 1, the semiconductor device may include a controller 1100, a test circuit 1200, and a memory driver 1300.

The controller 1100 may provide a command CMD and a clock signal CLK to the test circuit 1200. The command CMD may include a command signal, such as a read command, a write command or an active command, generated through address information.

In the present embodiment, the command CMD is inputted from an external source. However, an address may be inputted and used.

The test circuit 1200 may receive the command CMD and the dock signal CLK having a first frequency from the controller 1100, and generate a high-speed clock signal HCLK having a second frequency, corresponding to a half period of the clock signal CLK. The test circuit 1200 may provide the high-speed clock signal HCLK (that is, ‘HCLK_R’ in FIG. 1) and high-speed commands CMD_2R and CMD_2F synchronized with the high-speed clock signal HCLK to the memory driver 1300 during a test operation.

The test circuit 1200 may include a buffering unit 1210, a clock division unit 1220, a command synchronization unit 1230, a command decoding unit 1240, a clock doubling unit 1250, and a plurality of selection units 1280.

The buffering unit 1210 may include a first buffering unit 1211 and a second buffering unit 1212. The first buffering unit 1211 may receive the command CMD from the controller 1100 and buffer the received command CMD to generate an internal command CMDI, and the second buffering unit 1212 may receive the clock signal CLK from the controller 1100 and buffer the received clock signal CLK to generate an internal clock signal CLKI.

The clock division unit 1220 may divide the internal clock signal CLKI outputted from the second buffering unit 1212 into a rising clock CLK_R, a falling clock CLK_F, a command clock CLK_CMD, and a doubling clock CLKD. The rising clock CLK_R is a clock signal corresponding to a rising edge of the internal clock CLKI, the falling clock CLK_F is a clock signal corresponding to a falling edge of the internal clock CLKI, and the rising clock CLK_R and the falling clock CLK_F are used for synchronization of the internal command CMDI. The command clock CLK_CMD may be inputted to the command decoding unit 1240, and the doubling clock CLKD may be inputted to the clock doubling unit 1250.

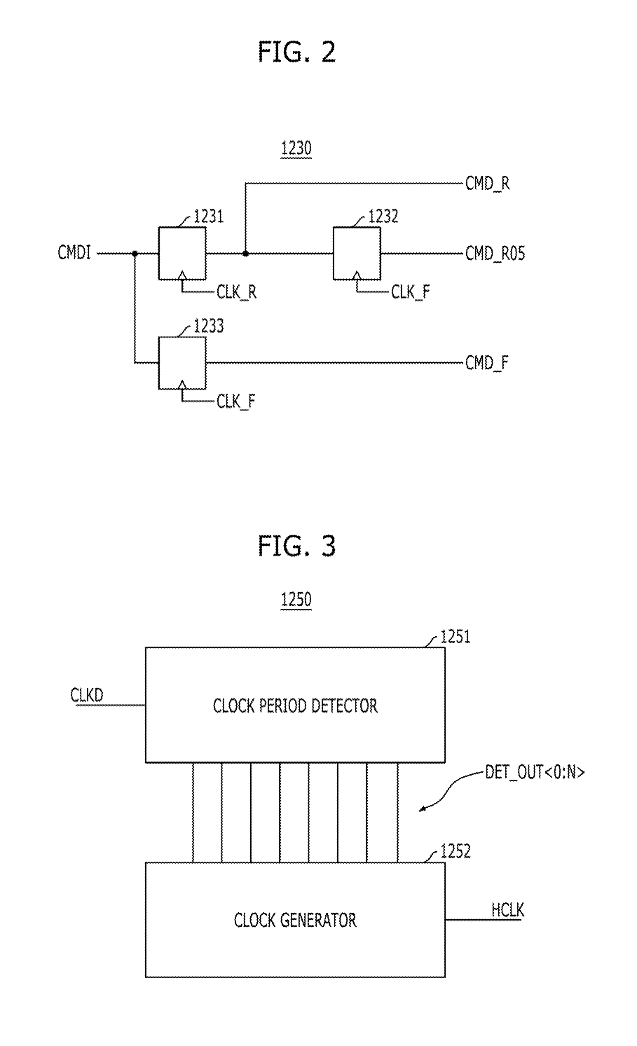

The command synchronization unit 1230 may synchronize the internal command CMDI outputted from the first buffering unit 1211 with the rising clock CLK_R and the falling clock CLK_F received from the clock division unit 1220, and output the synchronized commands. At this time, the internal command CMDI may be outputted as a rising command CMD_R synchronized with the rising clock. CLK_R and a falling command CMD_F synchronized with the falling clock CLK_F. The configuration and operation of the command synchronization unit 1230 will be described in detail with reference to FIG. 2.

The command decoding unit 1240 may receive the rising command CMD_R synchronized through the command synchronization unit 1230 in response to the command clock CLK_CMD outputted from the clock division unit 1220, and decode the received command to generate a single cycle command SCMD and a double cycle command DCMD. The single cycle command SCMD indicates that one command is activated during one cycle, and the double cycle command DCMD indicates that two commands are activated during one cycle.

The clock doubling unit 1250 may receive the doubling clock CLKD from the clock division unit 1220, detect a unit delay time of the doubling clock CLKD, and generate a high-speed clock signal HCLK corresponding to a half period of the unit delay time. At this time, a high-speed rising clock HCLK_R corresponding to a rising edge of the high-speed clock signal HCLK and a high-speed falling clock HCLK_F corresponding to a falling edge of the high-speed clock signal HCLK may be inputted to a high-speed command synchronization unit 1270. A high-speed command clock HCLK_COM serves as an input of a control signal generation unit 1260 for controlling a control signal based on the single cycle command SCMD and the double cycle command SCMD. The configuration and operation of the clock doubling unit 1250 will be described with reference to FIG. 3.

The control signal generation unit 1260 may generate a plurality of control signals RSEL_SC, RSEL_DC, FSEL_SC, and FSEL_DC in response to the high-speed command clock HCLK_CMD. The plurality of control signals RSEL_SC, RSEL_DC, FSEL_SC, and FSEL_DC pulse in a different manner depending on the signal cycle command SCMD and the double cycle command DCMD, in order to control the rising command CMD_R and the falling command CMD_F. In the case of the single cycle command SCMD, only two control signals RSEL_SC and FSEL_SC may be activated among the plurality of control signals RSEL_SC, RSEL_DC, FSEL_SC, and FSEL_DC. In the case of the double cycle command DCMD, all of the four control signals RSEL_SC, RSEL_DC, FSEL_SC, and FSEL_DC may be activated. In other words, when the command is the single cycle command SCMD, one command may be outputted during one cycle of the clock signal, and when the command is the double cycle command DCMD, two commands may be outputted during one cycle of the clock signal.

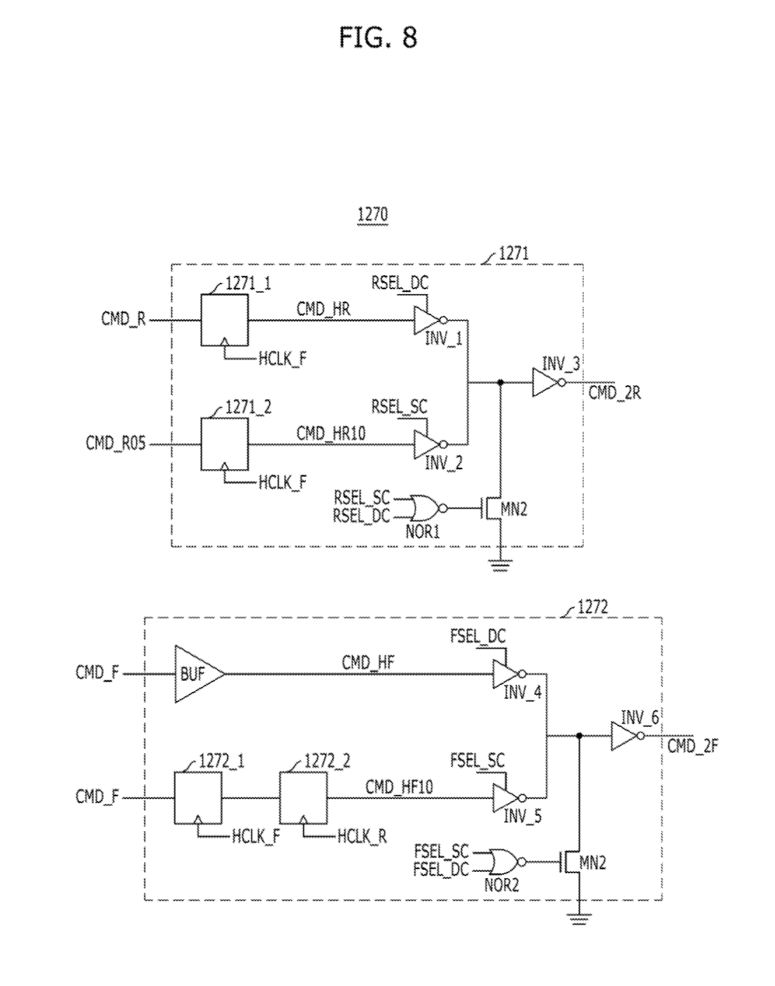

The high-speed command synchronization unit 1270 may synchronize the rising command CMD_R and the falling command CMD_F, outputted from the command synchronization unit 1230, with the high-speed rising clock HCLK_R and the high-speed falling clock HCLK_R, respectively, and output the synchronized commands. Furthermore, depending on whether the command is the single cycle command SCMD or the double cycle command DCMD, the high-speed command synchronization unit 1270 may be operated in response to the plurality of control signals RSEL_SC, RSEL_DC, FSEL_SC, and FSEL_DC. The configuration and operation of the high-speed command synchronization 1270 will be described in detail with reference to FIG. 8.

The plurality of selection units 1280 may include first to fourth selection units 1281 and 1284 which are controlled by a test mode signal TM.

The first selection unit 1281 may selectively output the rising command CMD_R outputted from the command synchronization unit 1230 or the high-speed rising command CMD_2R outputted from the high-speed command synchronization unit 1270 in response to the test mode signal TM. When the test mode signal TM is activated, the first selection unit 2181 may output the high-speed rising command CMD_2R.

The second selection unit 1282 may selectively output the falling command CMD_F outputted from the command synchronization unit 1230 or the high-speed falling command CMD_2F outputted from the high-speed command synchronization unit 1270 in response to the test mode signal TM. When the test mode signal TM is activated, the second selection unit 1282 may output the high-speed falling command CMD_2F.

The third selection unit 1283 may selectively output a phase-shifted rising clock signal QCLK_R or a phase-shifted high-speed rising dock signal QHCLK_R in response to the test mode signal TM. When the test mode signal TM is activated, the third selection unit 1283 may output the phase-shifted high-speed rising clock signal QHCLK_R.

The fourth selection unit 1284 may selectively output the rising clock CLK_R or the high-speed rising clock HCLK_R in response to the test mode signal TM. When the test mode signal TM is activated, the fourth selection unit 1284 may output the high-speed rising clock FICLK_R.

The test mode signal TM may be generated from a mode register set (MRS) or received from an external source. The test mode signal TM may be activated during a test operation, and the test operation may be performed in a device which performs a high-frequency operation.

The memory driver 1300 may receive the high-speed clock signal HCLK (that is, the high-speed rising clock HCLK_R) and the high-speed commands CMD_2R and CMD_2F synchronized with the high-speed clock signal HCLK from the test circuit 1200, during a test operation.

The memory driver 1300 may include an internal signal input unit 1310 and an internal circuit unit 1320. The internal signal input unit 1310 may include a command selector 1311 and a clock controller 1312.

The command selector 1311 may selectively output the high-speed rising command CMD_2R or the high-speed falling command CMD_2F in response to the phase-shifted high-speed rising clock signal QHCLK_R outputted from the test circuit 1200, during a test operation. During the test operation, the phase-shifted high-speed rising clock signal QHCLK_R may be activated, and thus the high-speed rising command CMD_2R may be outputted as an output command FCMD. The output command FCMD may be buffered through a buffer 1313 and inputted to the internal circuit unit 1320 through a command pad P_CMD.

The clock controller 1312 may selectively output a power supply voltage VOD or a ground voltage VSS in response to the high-speed clock signal HCLK (that is, the high-speed rising clock HCLK_R) outputted from the test circuit 1200 during a test operation. During the test operation, the high-speed clock signal HCLK may be activated, and thus the ground voltage VDD may be outputted as an output clock signal FCLK. The output clock signal FCLK may be buffered through a buffer 1314 and inputted to the internal circuit unit 1320 through a clock pad P_CLK.

The internal circuit unit 1320 may perform an internal operation in response to the output command FCMD and the output clock signal FCLK which are transferred through the command pad P_CMD and the clock pad P_CLK.

Hereafter, the operation of the semiconductor device embodiment will be described with reference to FIG. 2.

FIG. 2 is a detailed block diagram of the command synchronization unit which is a component of the test circuit of FIG. 1 in accordance with the embodiment of the present invention.

Referring to FIG. 2, the command synchronization unit 1230 may include three latches 1231, 1232, and 1233.

First, the command synchronization unit 1230 may latch the internal command CMDI with the rising clock CLK_R to generate the rising command CMD_R, and latch the internal command CMDI with the falling clock CLK_F to generate the falling command CMD_F.

Then, the command synchronization unit 1230 may latch the rising command CMD_R with the falling clock CLK_F to generate a shifted rising command CMD_R05 where the phase is shifted by a half clock.

FIG. 3 is a detailed block diagram of the clock doubling unit which is a component of the test circuit of FIG. 1 in accordance with the embodiment of the present invention.

Referring to FIG. 3, the clock doubling unit 1250 may include a clock period detector 1251 and a clock generator 1252.

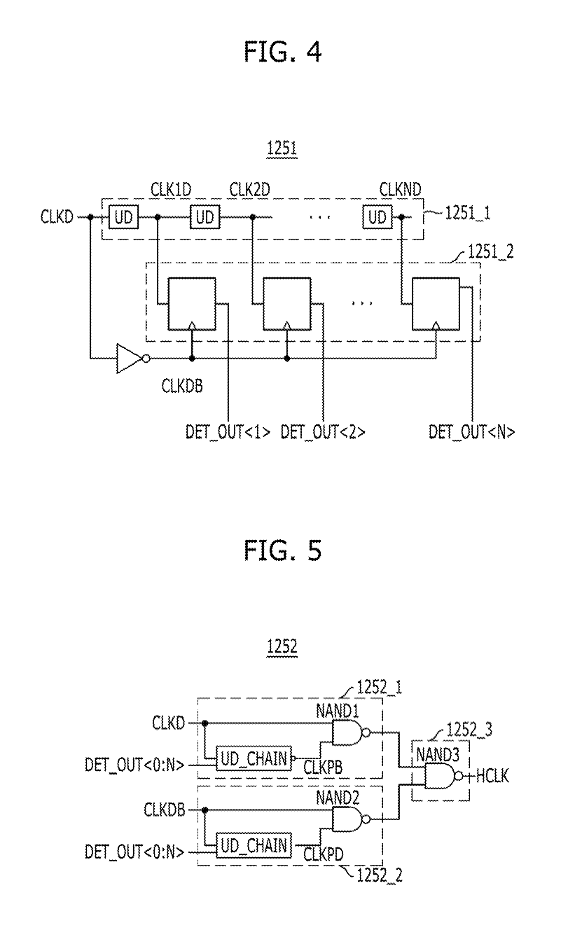

The clock period detector 1251 may delay a first-frequency clock signal CLKD through a plurality of unit delay circuits, and detect the period of the clock signal CLKD as the number of unit delay circuits used for unit delay of the clock signal CLKD. That is, the clock period detector 1251 may generate a detection signal DET_OUT_<0:N> having information on how many unit delays are included in the period of the clock signal CLKD. The configuration and operation of the clock period detector 1251 will be described in detail with reference to FIG. 4.

The first-frequency clock signal CLKD may include the doubling clock CLKD outputted from the clock division unit 1220 illustrated in FIG. 1.

The clock generator 1252 may generate a clock signal delayed by a half period of the clock signal CLKD in response to the detection signal DET_OUT<0:N> outputted from the clock period detector 1251, and generate a second-frequency clock signal HCLK having a period corresponding to edges of the clock signal CLKD and the delayed clock signal, that is, the high-speed clock signal HCLK. The configuration and operation of the clock generator 1252 will be described in detail with reference to FIG. 5.

FIG. 4 is a detailed block diagram of the clock period detector, which is a component of the clock doubling unit of FIG. 3, in accordance with the embodiment of the present invention.

Referring to FIG. 4, the clock period detector 1251 may include a plurality of unit delays 1251_1 and a plurality of latches 1251_2.

The plurality of unit delays 1251_1 may sequentially delay the clock signal CLKD and generate a plurality of delayed clock signals CLK1D, CLK2D, . . . , CLKND. That is, the clock signal CLKD may be sequentially delayed by the unit delay (UD), and outputted as the first delayed clock signal CLK1D, the second delayed clock signal CLK2D, . . . , and the Nth delayed clock signal CLKND.

The plurality of latches 1251_2 may receive the plurality of delayed clock signals CLK1D, CLK2D, . . . , CLKND, latch the received signals with a clock bar signal CLKDB obtained by inverting the clock signal CLKD, and output a plurality of detection signals DET_OUT<0:N>. That is, the number of unit delays 1251-1 may be detected through the detection signals DET_OUT<0:N>.

FIG. 5 is a detailed block diagram of the clock generator, which is a component of the clock doubling unit of FIG. 3, in accordance with the embodiment of the present invention.

Referring to FIG. 5, the dock generator 1252 may include a first edge detector 1252_1, a second edge detector 1252_2, and an output section 1252_3. The first edge detector 1252_1 may detect a rising edge of the dock signal CLKD in response to the plurality of detection signals DET_OUT<0:N> and output a pulse signal delayed by a half period of the clock signal CLKD. The second edge detector 1252_2 may detect a failing edge of the clock signal CLKD in response to the plurality of detection signals DET_OUT<0:N> and output a pulse signal delayed by a half period of the clock signal CLKD.

Each of the first and second edge detectors 1252_1 and 1252_2 may include a delay chain UD_CHAIN and a NAND gate NAND1 or NAND2.

The delay chain UD_CHAIN of the first edge detector 1252_1 may output a pulse signal CLKPB delayed by a half period of the clock signal CLKD in response to the clock signal CLKD and the detection signals DET_OUT<0:N>, and the NAND gate NAND1 may detect a rising edge of the clock signal CLKD and output a pulse signal in response to the clock signal CLKD and the delayed pulse signal CLKPB.

The delay chain UD_CHAIN of the second edge detector 1252_2 may output a pulse signal CLKDP delayed by a half period of the clock bar signal CLKDB in response to the clock bar signal CLKDB and the detection signals DET_OUT<0:N>, and the NAND gate NAND2 may detect a rising edge of the clock bar signal CLKBD and output a pulse signal in response to the clock bar signal CLKDB and the delayed pulse signal CLKDBP. That is, the second edge detector 1252_2 may detect a falling edge of the clock signal CLKD and output a pulse signal.

The output section 1252_3 may output a signal HCLK which toggles at each rising edge and falling edge of the clock signal CLKD in response to the pulse signals outputted from the first and second edge detectors 1252_1 and 1252_2. At this time, the output signal HCLK is a high-speed clock signal and has a half period of the clock signal CLKD. Thus, the frequency may be doubled.

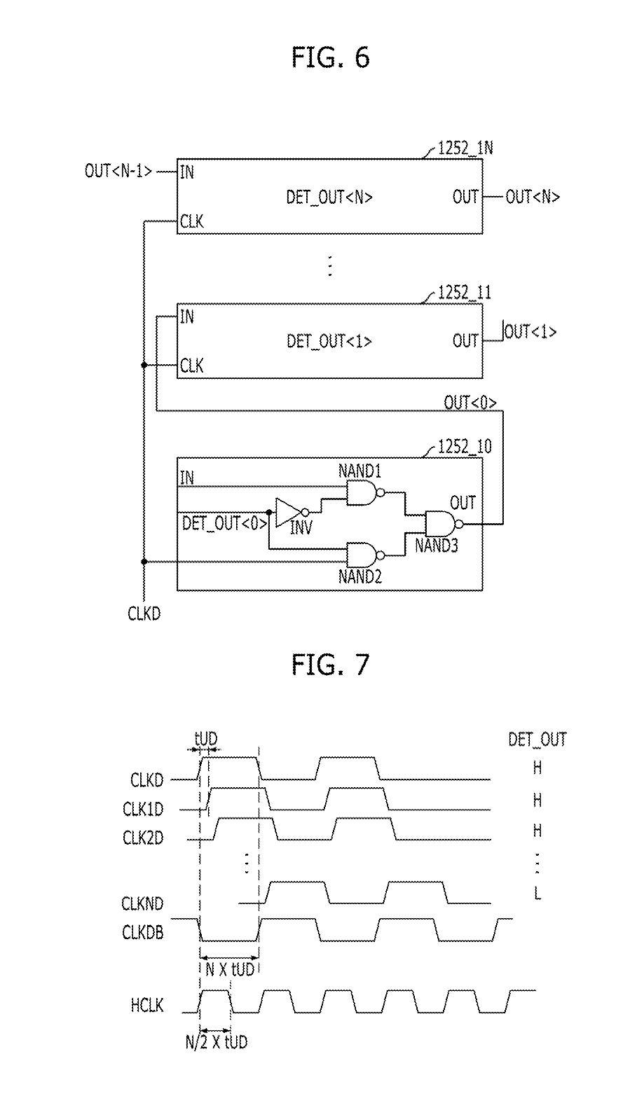

FIG. 6 is a detailed block diagram of the delay chain which is a component of the clock generator of FIG. 5 in accordance with the embodiment of the present invention.

Referring to FIG. 6, the delay chain UD_CHAIN may include a plurality of delay sections 1252_10 to 1252_11, . . . , 1252_1N. Each of the delay sections 1252_10 to 1252_11, . . . , 1252_1N has a unit delay time corresponding to a half of the unit delay time of the unit delays 1251_1 illustrated in FIG. 4. In other words, when each of the unit delays 1251_1 has a delay time of tUD, each of the delay sections 1252_10 to 1252_11, . . . , 1252_1N illustrated in FIG. 6 has a delay time of ½*tUD.

The delay sections 1252_10 to 1252_11, . . . , 1252_1N may receive the clock signal CLKD and the detection signals DET_OUT<0:N>, respectively. Since the plurality of delay sections 1252_10 to 1252_11, . . . , 1252_1N have the same configuration and perform the same operation, the first delay section 1252_11 will be described as a representative example. The first delay section 1252_11 may include one inverter INV and three NAND gates NAND1, NAND2, and NAND3.

The first NAND gate NAND1 may receive an input signal IN and the detection signal DET_OUT<0> inverted through the inverter INV, and the second NAND gate NAND2 may receive the detection signal DET_OUT<0> and the clock signal CLKD. The signals outputted through logical operations of the first and second NAND gates NAND1 and NAND2 are inputted to the third NAND gate NAND3, and the third NAND gate NAND3 outputs a signal OUT<0> through a logical operation. The output signal OUT<0> serves as an input signal IN of the next delay section 1252_11. Through the plurality of delay sections 1252_10 to 1252_11, . . . , 1252_1N a final delayed signal OUT<N> may be outputted.

Thus, the pulse signal delayed by a half period of the clock signal CLKD may be outputted through the delay chain UD_CHAIN.

FIG. 7 is a timing diagram illustrating the operation of the clock doubling unit of FIG. 3 in accordance with the embodiment of the present invention.

Referring to FIGS. 3 to 7, the clock signal CLKD may be delayed by the unit delay of tUD, and sequentially outputted as the first delayed clock signal CLK1D, the second delayed clock signal CLK2D, . . . , and the N-th delayed clock signal CLKND. Then, the first delayed clock signal CLK1D, the second delayed clock signal CLK2D, . . . , and the N-th clock signal CLKND may be latched with the clock bar signal CLKDB obtained by inverting the clock signal CLKD, and outputted as the plurality of detection signals DET_OUT<0:N>.

When the detection signal DET_OUT<N> of the N-th delayed clock signal CLKND is low (L), a pulse width based on the unit delay of the clock signal CLKD, that is, the period becomes ‘N*tUD’. Thus, the clock generator 2152 may generate a high-speed clock signal HCLK having a pulse width of N/2*tUD corresponding to a half pulse width of N*tUD based on the unit delay of the clock signal CLKD.

The high-speed clock signal HCLK generated in such a manner has a period corresponding to a half period of the clock signal CLKD. Thus, the clock frequency may be doubled to enable high-speed operation.

FIG. 8 is a detailed block diagram of the high-speed command synchronization unit which is a component of the test circuit of FIG. 1 in accordance with the embodiment of the present invention.

Referring to FIG. 8, the high-speed command synchronization unit 1270 may include a high-speed rising command generator 1271 and a high-speed falling command generator 1272.

The high-speed rising command generator 1271 may synchronize the rising command CMD_R and the shifted rising command CMD_R05, outputted from the command synchronization unit 1230 of FIG. 1, with the high-speed falling clock HCLK_F through latches 1271_1 and 1271_2, and output the synchronized commands as signals CMD_HR and CMD_HR10, respectively. The high-speed falling dock HCLK_F is a signal corresponding to the falling edge of the high-speed clock signal HCLK.

The output signals CMD_HR and CMDHR10 may be inputted to inverters INV_1 and INV_2, respectively. The inverters INV_1 and INV_2 may be operated in response to the control signals RSEL_DC and RSEL_SC of which the pulses are generated in a different manner depending on whether the command is the single cycle command SCMD or the double cycle command DCMD. The signal CMD_HR outputted through the first latch 1271_1 may be controlled in response to the second control signal RSEL_DC, and the signal CMD_HR10 outputted through the second latch 1271_2 may be controlled in response to the first control signal RSEL_SC. During the operation for the single cycle command SCMD, only the first control signal RSEL_SC may be activated, and the second control signal RSEL_DC may be deactivated. During the operation for the double cycle command DCMD, both of the first and second control signals RSEL_SC and RSEL_DC may be activated. Then, a signal CMD_2R may be finally outputted through an inverter INV_3.

The high-speed falling command generator 1272 may buffer the falling command CMD_F, outputted from the command synchronization unit 1230 illustrated in FIG. 1, through a buffer BUF and output the buffered signal as a signal CMD_HF. The high-speed falling command generator 1272 may synchronize the falling command CMD_F with the high-speed falling clock HCLK_F and synchronize the synchronized signal with the high-speed rising clock HCLK_R once more through two latches 1271_1 and 1272_2, and then output the synchronized signal as a signal CMD_HF10. The high-speed falling clock HCLK_F is a signal corresponding to a falling edge of the high-speed clock signal HCLK, and the high-speed rising clock HCLK_R is a signal corresponding to a rising edge of the high-speed clock signal HCLK.

The output signals CMD_HF and CMD_HF10 may be inputted to inverters INV_4 and INV_5, respectively. The inverters INV_4 and INV_5 may operate in response to the control signals FSEL_DC and FSEL_SC of which the pulses are generated in a different manner depending on whether the command is the single cycle command SCMD or the double cycle command DCMD. The signal CMD_HF outputted through the buffer BUF may be controlled in response to the fourth control signal FSEL_DC, and the signal CMD_HF10 outputted through the two latches 1272_1 and 1272_2 may be controlled in response to the third control signal FSEL_SC. During the operation for the single cycle command SCMD, only the third control signal FSEL_SC may be activated, and the fourth control signal FSEL_DC may be deactivated. During the operation for the double cycle command DCMD, both of the third and fourth control signals FSEL_SC and FSEL_DC may be activated. Then, a signal CMD_2F may finally be outputted through an inverter INV_6.

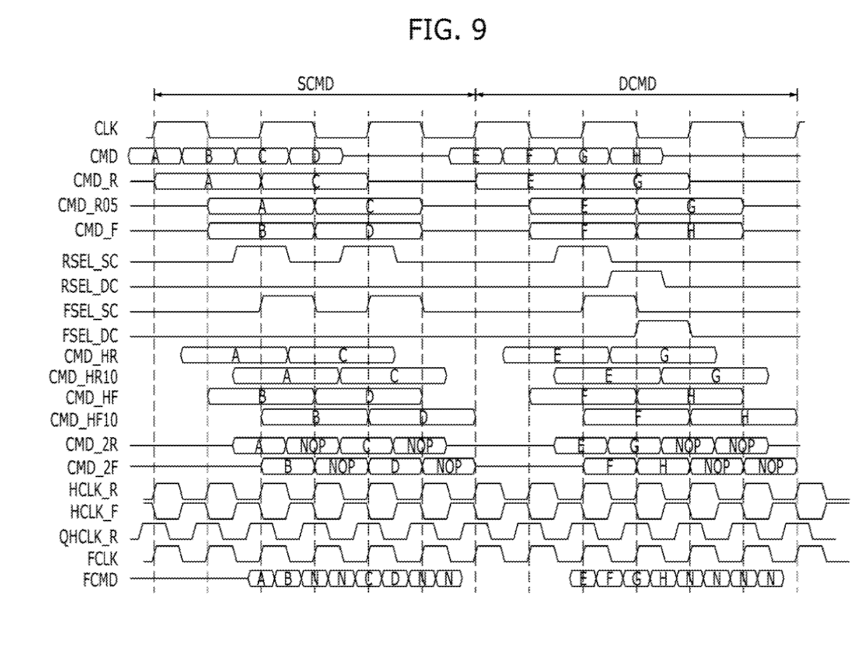

Hereafter, the operation of the semiconductor device will be described in detail with reference to FIG. 9.

FIG. 9 is a timing diagram of the operation of the semiconductor device illustrated in FIGS. 1 to 8.

Referring to FIGS. 1 to 9, the operation of the semiconductor device may be divided into a single cycle command section SCMD and a double cycle command section DCMD.

First, the operation of the single cycle command section SCMD will be described.

The clock signal CLK and the command CMD may be inputted from the controller 1100. The command CMD may be synchronized with failing and rising edges of the clock signal CLK through the command synchronization unit 1230 and then outputted as the rising command CMD_R, the shifted rising command CMD_R05, and the falling command CMD_F.

The rising command CMD_R, the shifted rising command CMD_R05, and the falling command CMD_F may be inputted to the high-speed command synchronization unit 1270, and then synchronized with the high-speed rising clock HCLK_R and the high-speed falling clock HCLK_F. At this time, the first control signal RESL_SC and the third control signal FSEL_SC may be activated during the single cycle command SCMD.

As illustrated in FIG. 8, the rising command CMD_R may be synchronized with the high-speed falling clock HCLK_F through the first latch 1271_1 and outputted as a signal CMD_HR. The delayed rising command CMD_RO5 may be synchronized with the high-speed falling clock HCLK_F through the second latch 1271_2 and outputted as a signal CMD_HR10. The signals CMD_HR and CMD_HR10 outputted through the first and second latches 1271_1 and 1271_2 may be controlled by the first and second control signals RSEL_SC and RSEL_DC, and finally outputted as the high-speed rising command CMD_2R.

Furthermore, the falling command CMD_F may be buffered through the buffer BUF and outputted as a signal CMD_HF and the falling command CMD_F may be synchronized through the two latches 1272_1 and 1272_2 and outputted as a signal CMD_FH10. The output signals CMD_HF and CMD_HF10 may be controlled by the third and fourth control signals FSEL_SC and FSEL_DC, and finally outputted as the high-speed falling command CMD_2F.

Referring to the high-speed rising command CMD_2R and the high-speed failing command CMD_2F, it can be seen that one command is outputted during one cycle of the clock signal CLK. This is because only the first and third control signals RSEL_SC and RSEL_SC are activated during the single cycle command section SCMD.

During the double cycle command section DCMD, all of the first to fourth control signals RSEL_SC, RSEL_DC, FSEL_SC, and FSEL_DC are activated, unlike the single cycle command section SCMD. Thus, the high-speed rising command CMD_2F and the high-speed falling command CMD_2F may be outputted twice during one cycle.

As such, the high-speed clock signal HCLK having a period corresponding to a half period of the clock signal CLK may be generated and outputted through the test circuit 1200 illustrated in FIG. 1. Thus, the command CMD may be synchronized with the high-speed rising clock HCLK_R and the high-speed falling clock HCLK_F and outputted as the high-speed commands CMD_2R and CMD_2F. The high-speed rising command CMD_2R and the high-speed falling command CMD_2F may be inputted to the memory driver 1300, and then synchronized with the phase-shifted high-speed rising clock signal QHCLK_R to generate the final command FCMD. The generated final command FCMD, that is, the high-speed command, and the final clock signal FCLK, that is, the high-speed clock signal, may be inputted to the internal circuit unit 1320 within the memory driver 1300, and then used to drive a memory.

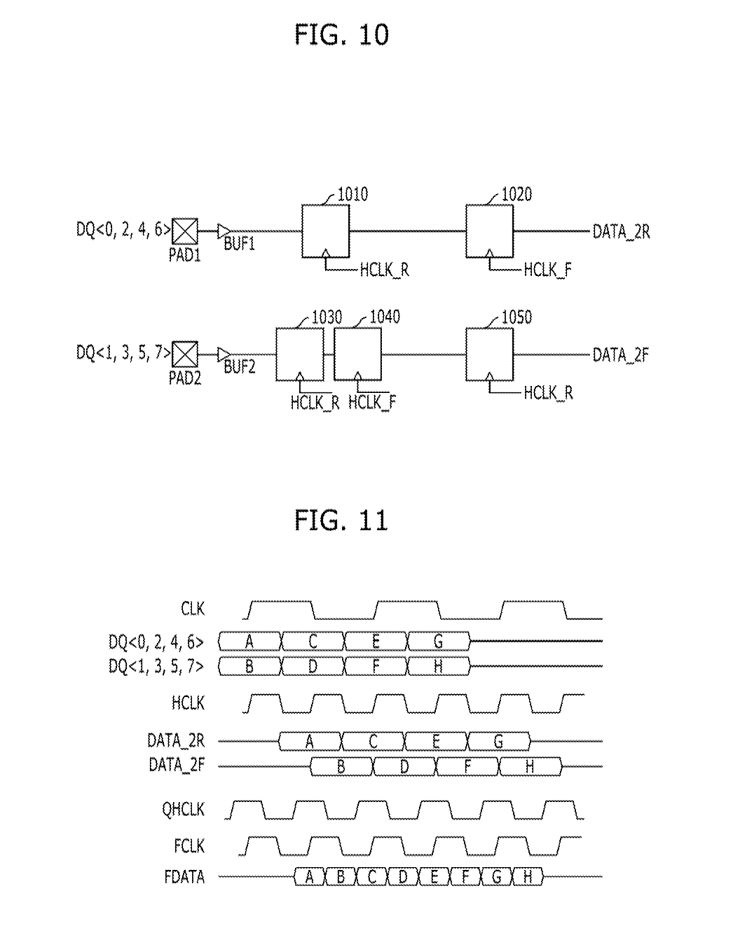

FIG. 10 is a circuit diagram of a write circuit for writing data using the high-speed clock signal generated by the clock doubling unit of FIG. 1.

Referring to FIG. 10 the write circuit may sequentially receive data DQ 0, 2, 4, 6> and DQ 1, 3, 5, 7> through two pads PAD1 and PAD2, synchronize the received data with the high-speed rising clock HCLK_R and the high-speed falling dock HCLK_F through buffers BUF1 and BUF2 and a plurality of latches 1010 to 1050, and output the synchronized data DATA_2R and DATA_2F. The high-speed rising dock HCLK_R and the high-speed falling clock HCLK_F for synchronization may be generated through the clock doubling unit 1250 illustrated in FIG. 1.

The data DQ<0, 2, 4, 6> may be inputted to the first pad PAD1 at even orders, and the data DQ<1, 3, 5, 7> may be inputted to the second pad PAD2 at odd orders. The operation of the write circuit will be described in detail with reference to FIG. 11.

FIG. 11 is a timing diagram illustrating the operation of the write circuit of FIG. 10.

Referring to FIGS. 10 and 11, the data DQ<0, 2, 4, 6> and DQ<1, 3, 5, 7> may be inputted through the first and second pads PAD1 and PAD2. The data DQ<0, 2, 4, 6> inputted through the first pad PAD1 may be represented by A, C, F, and G, and the DQ 1, 3, 5, 7> inputted through the second pad PAD2 may be represented by B, D, F, and H. The input data DQ<0, 2, 4, 6> and DQ<1, 3, 5, 7> may be synchronized with rising and falling edges of the high-speed clock signal HCLK, and outputted as data DATA_2R and DATA_2F. The output data may be synchronized with a phase-shifted high-speed dock signal QHCLK and outputted as final data FDATA.

The write circuit of the data may alternately receive the data DQ<0, 2, 4, 6> and the data DQ<1, 3, 5, 7> through the two data pads PAD1 and PAD2.

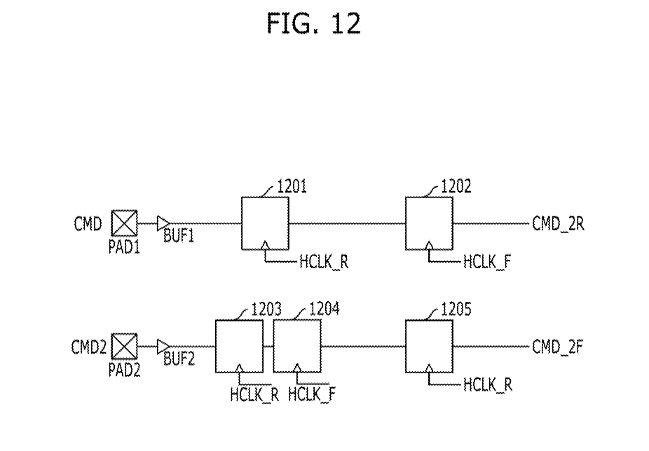

FIG. 12 is a circuit diagram where the number of command pads is doubled in accordance with another embodiment of the present invention.

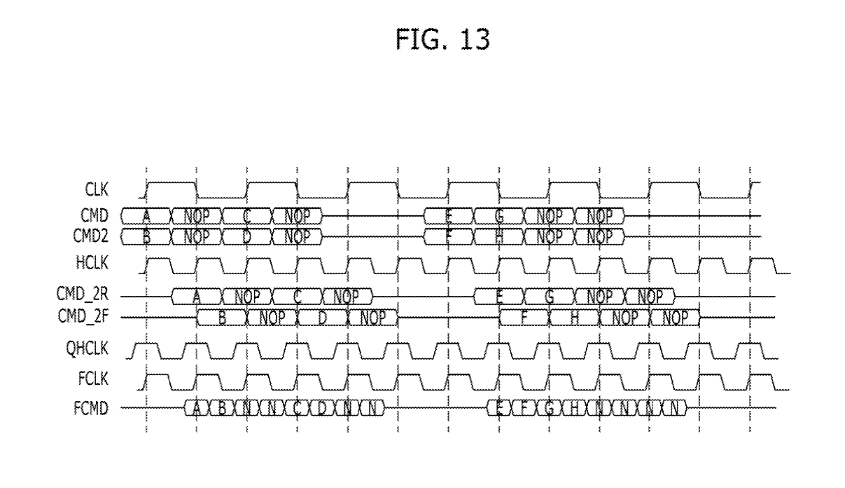

Referring to FIG. 12, the circuit in which the number of command pads is doubled may receive commands CMD and CMD2 through two command pads PAD1 and PAD2, synchronize the received commands with a high-speed rising clock HCLK_R and a high-speed falling clock HCLK_F through buffers BUF1 and BUF2 and a plurality of latches 1201 to 1205, and output the synchronized commands as commands CMD_2R and CMD_2F. The high-speed rising clock HCLK_R and the high-speed falling clock HCLK_F for synchronization may be generated through the clock doubling unit 1250 illustrated in FIG. 1. The operation of the circuit illustrated in FIG. 12 will be described with reference to FIG. 13.

FIG. 13 is a timing diagram illustrating the operation of the circuit of FIG. 12.

Referring to FIGS. 12 and 13, the commands CMD and CMD2 may be inputted through the two command pads PAD1 and PAD2. The input commands CMD and CMD2 may be synchronized with rising and falling edges of the high-speed clock signal HCLK and outputted as commands CMD_2R and CMD_2F. Then, the output commands CMD_2R and CMD_2F may be synchronized with a phase-shifted high-speed clock signal QHCLK and outputted as a final command FCMD.

When only one command pad is provided as illustrated in FIG. 1, a test pattern may be limited. In other words, when the command CMD is inputted from an external source, the command CMD is inputted on the basis of an external clock signal CLK, and the internal clock signal, that is, the high-speed clock signal HCLK generated through a doubling operation, has a frequency two times higher than the clock signal CLK. Since the command CMD is inputted on the basis of the external clock signal CLK, theinterval between the commands is fitted to the speed of the clock signal CLK.

Thus, during a test operation, a command pattern may be inputted through the two command pads PAD1 and PAD2, in order to operate based on the speed of the high-speed clock signal HCLK.

In FIG. 9, although the command CMD is inputted as A, B, C, and D, the final command FCMD is outputted as A, B, N, N, C, D, N, and N. In FIG. 13, however, the command CMD is inputted to the first pad PAD1 as A, NOP, C, and NOP, the command CM2 is inputted to the second pad PAD2 as B, NOP, D, and NOP and the final command FCMD may be outputted as A, B, N, N, C, D, N, and N. At this time, another command may be inputted instead of NOP, and thus another operation for the inputted command may be performed. That is, as the two command pads are provided, the test operation may be performed in various manners.

In accordance with the embodiments of the present invention, a high-speed dock signal having a frequency two times higher than the clock signal may be generated through clock doubling. Therefore, a test may be performed where a semiconductor device is operating at high speed.

Although various embodiments have been described for illustrative purposes, it will be apparent to those skilled in the art that various changes and modifications may be made without departing from the spirit and scope of the invention as defined in the following claims.

What is claimed is:

1. A clock controller comprising:
a dock period detector suitable for delaying a first clock signal through a plurality of unit delay circuits, and outputting a detection signal by detecting a period of the first clock signal as the number of unit delay circuits used for unit delay of the first clock signal among the unit delay circuits; and
a clock generator suitable for generating a delay clock signal delayed by a half period of the first clock signal in response to the detection signal outputted from the clock period detector, and generating a second clock signal having a period corresponding to edges of the first clock signal and the delay clock signal.

2. The clock controller of claim 1, wherein the plurality of unit delay circuits sequentially delays the first clock signal and outputs a plurality of delayed clock signals,
wherein the clock period detector further comprises:
a plurality of latches suitable for synchronizing the plurality of delayed clock signals with a clock bar signal complementary to the first clock signal and outputting the detection signal.

3. The clock controller of claim wherein the clock aerator comprises:
a first edge detector suitable for detecting a rising edge of the first clock signal in response to the detection signal of the clock period detector, and outputting a first pulse signal delayed by the half period of the first clock signal;
a second edge detector suitable for detecting a falling edge of the first clock signal in response to the detection signal of the clock period detector, and outputting a second pulse signal delayed by the half period of the first clock signal; and
an output section suitable for outputting the second clock signal which toggles at each of the rising and falling edges of the first clock signal in response to the first and second pulse signals outputted from the first and second edge detectors.

4. The clock controller of claim 1, wherein a second frequency of the second clock signal is higher than a first frequency of the first clock signal.

5. A test device comprising:
a buffering unit suitable for receiving a command and a first clock signal from an external source, buffering the command and the first clock signal, and outputting an internal command and an internal clock signal;
a command synchronization unit suitable for synchronizing the internal command with the internal clock signal to output a synchronized command;
a clock doubling unit suitable for detecting a unit delay time of the internal clock signal in response to the internal clock signal, and generating a second clock signal having a period corresponding to a half period of the unit delay time;
a high-speed command synchronization unit suitable for synchronizing the synchronized command outputted from the command synchronization unit with the second clock signal to output a high-speed command; and
a plurality of selection units suitable for selectively outputting the internal clock signal and the synchronized command outputted from the command synchronization unit or the second clock signal and the high-speed command synchronized with the second-frequency clock signal, in response to a test signal.

6. The test device of claim wherein the clock doubling unit comprises:
a clock period detector suitable for delaying the internal clock signal through a plurality of unit delay circuits, and outputting a detection signal by detecting a period of the internal clock signal as the number of unit delay circuits used for the unit delay time among the unit delay circuits; and
a clock generator suitable for generating a delay clock signal delayed by a half period of the internal clock signal in response to the detection signal, and generating the second clock signal having the period corresponding to edges of the internal clock signal and the delay clock signal.

7. The test device of claim 6, wherein the plurality of unit delay circuits sequentially delays the internal clock signal and outputs a plurality of delayed clock signals,
wherein the clock period detector further comprises:
a plurality of latches suitable for synchronizing the plurality of delayed clack signals with a clock bar signal complementary to the internal clock signal, and outputting the detection signal.

8. The test device of claim 7, wherein the clock generator comprises:
a first edge detector suitable for detecting a rising edge of the internal clock signal in response to the detection signal of the clock period detector, and outputting a first pulse signal delayed by the half period of the internal clock signal;
a second edge detector suitable for detecting a falling edge of the internal clock signal in response to the detection signal of the clock period detector, and outputting a second pulse signal delayed by the half period of the internal clock signal; and
an output section suitable for outputting the second clock signal which toggles at each of the rising and falling edges of the internal clock signal in response to the first and second pulse signals outputted from the and second edge detectors.

9. The test device of claim 5, wherein the plurality of selection units comprise:
a first selection unit suitable for selectively outputting the synchronized command synchronized with a rising edge of the internal clock signal or the high-speed command synchronized with a rising edge of the second clock signal in response to the test signal;
a second selection unit suitable for selectively outputting the synchronized command synchronized with a falling edge of the internal clock signal or the high-speed command synchronized with a falling edge of the second clock signal in response to the test signal;
a third selection unit suitable for selectively outputting a clock signal where the phase is shifted by a half period or a high-speed clock signal where the phase is shifted by a half period, in response to the test signal; and
a fourth selection unit suitable for selectively outputting the internal clock signal or the second clock signal in response to the test signal.

10. The test device of claim 5, further comprising:
a command decoding unit suitable for generating a single command and a double command in response to the internal clock signal; and
a control signal generation unit suitable for generating a control signal for controlling the high-speed command synchronization unit based on the single command or the double command, in response to the second dock signal outputted from the clock doubling unit.

11. The test device of claim 5, wherein a second frequency of the second clock signal is higher than a first frequency of the first clock signal.

12. A semiconductor device comprising:
a test circuit suitable for receiving a first clock signal and a first command from an external source, generating a second clock signal having a period corresponding to a half period of the first clock signal, and outputting the second clock signal and a second command synchronized with the second clock signal during a test operation; and
a memory driver suitable for operating in response to the second clock signal and the second command synchronized with the second clock signal from the test circuit during the test operation.

13. The semiconductor device of claim 1, further comprising:
a controller suitable for providing the first clock signal and the first command to the test circuit.

14. The semiconductor device of claim 12, wherein a second frequency of the second clock signal is higher than a first frequency of the first dock signal.
